(19) United States
(12) Patent Application Publication
(10) Pub. No.: US 2026/0029485 A1
(43) Pub. Date: Jan. 29, 2026

(54) Battery Cell Degradation Diagnosis Method and Battery System Using the Same

(71) Applicant: LG Energy Solution, Ltd., Seoul (KR)

(72) Inventors: Bokyun Lee, Daejeon (KR); Changyong Song, Daejeon (KR)

(73) Assignee: LG Energy Solution, Ltd., Seoul (KR)

(21) Appl. No.: 19/099,209

(22) PCT Filed: Aug. 3, 2023
(86) PCT No.: PCT/KR2023/011448

§ 371 Date: Jan. 28, 2025

(30) Foreign Application Priority Data
Sep. 15, 2022 (KR) 10-2022-0116272

(51) Int. Cl. G01R 31/392; G01R 31/367; G01R 31/3842; G01R 31/396

(52) U.S. Cl. CPC G01R 31/392; G01R 31/367; G01R 31/3842; G01R 31/396

(57) ABSTRACT

A method for diagnosing degrees of degradation of a plurality of battery cells constituting a battery pack by a battery management system includes: computing accumulated energy for the battery pack using a battery pack current flowing through the battery pack and a battery pack voltage that is a voltage of the battery pack; calculating a cell capacity of each of the plurality of battery cells every predetermined cell capacity calculation cycle; calculating a cell capacity difference every cell capacity calculation cycle for each of the plurality of battery cells; calculating a degree of change in cell capacity difference for each of the plurality of battery cells every accumulation cycle during which the accumulated energy increases by a predetermined unit; and diagnosing whether each battery cell is abnormal according to a result of comparing the degree of change in cell capacity difference calculated every accumulation cycle with a predetermined threshold value.

### CROSS-REFERENCE TO RELATED APPLICATIONS

This application is a national phase entry under 35 U.S.C. § 371 of International Application No. PCT/KR2023/011448 filed on Aug. 3, 2023, which claims priority from Korean Patent Application No. 10-2022-0116272 filed on Sep. 15, 2022, all of which are incorporated herein by reference.

### BACKGROUND

A battery includes a plurality of battery cells, and a cell capacity of each of the plurality of battery cells degrades as the battery is used. If degradation rates of the plurality of battery cells are similar, a cell capacity difference between the plurality of battery cells may be within an allowable range. However, if there is a defective battery cell among the plurality of battery cells, the cell capacity difference between the defective battery cell and other battery cells may increase.

A battery management system may monitor a degree of cell capacity degradation for each of the plurality of battery cells and diagnose a battery cell of which a degree of cell capacity degradation is greater than those of the other battery cells as a defective cell when a difference between the plurality of degrees of cell capacity degradation of the plurality of battery cells is greater than or equal to a predetermined threshold value. However, since the degradation of the battery cell progresses over a considerable period of time, it takes a considerable amount of time for the cell capacity of the battery cell to degrade to a condition for diagnosing a defect. During this period, a battery cell of which a degree of cell capacity degradation is large may cause damage to the other battery cells of which degrees of cell capacity degradation are relatively small, which may eventually lead to damage to the entire battery.

### BRIEF SUMMARY

The technology generally relates to a method for diagnosing a degree of degradation of a battery cell and a battery system using the same capable of detecting a defective battery cell before damage to a battery occurs.

Aspects of the disclosure provide for a battery system including: a battery pack including a plurality of battery cells; a current sensor that measures a current flowing through the battery pack, and generates a current sensing signal indicating the measured battery pack current; a cell monitoring integrated circuit (IC) that measures a battery pack voltage of the battery pack and a cell voltage of each of the plurality of battery cells, and generates a voltage sensing signal indicating the measured battery pack voltage and the measured plurality of cell voltages; and a main control circuit that computes accumulated energy for the battery pack using the current sensing signal and the voltage sensing signal, calculates a cell capacity of each of the plurality of battery cells every predetermined cell capacity calculation cycle, calculates a degree of change in cell capacity difference for each of the plurality of battery cells every accumulation cycle during which the accumulated energy increases by a predetermined unit, and diagnoses whether each battery cell is abnormal according to a result of comparing the degree of change in cell capacity difference calculated every accumulation cycle with a predetermined threshold value.

In some examples, the main control circuit may include an energy accumulation unit that computes one of charging energy and discharging energy for the battery pack as the accumulated energy, using a battery pack current indicated by the current sensing signal and a battery pack voltage indicated by the voltage sensing signal.

In some examples, the energy accumulation unit may calculate accumulated energy by multiplying a battery pack current and a battery pack voltage every monitoring cycle during a charging period in which the battery pack is charged to calculate charging energy, and integrating the charging energy calculated during the charging period, or calculate accumulated energy by multiplying a battery pack current and a battery pack voltage every monitoring cycle during a discharging period in which the battery pack is discharged to calculate discharging energy, and integrating the discharging energy calculated during the discharging period.

In some examples, the main control circuit may include a cell capacity calculation unit that calculates cell capacities for each of the plurality of battery cells in units of the cell capacity calculation cycle, and stores the calculated plurality of cell capacities, the cell capacity calculation cycle being a period from a time point when the main control circuit is powered on to a time point when the main control circuit is powered off.

In some examples, the cell capacity calculation unit may accumulate a current flowing through each of the plurality of battery cells during the cell capacity calculation cycle and calculate an accumulated current amount of each of the plurality of battery cells, calculate an SOC change amount of each of the plurality of battery cells during the cell capacity calculation cycle, and calculate a cell capacity by dividing the accumulated current amount by the SOC change amount during the cell capacity calculation cycle for each of the plurality of battery cells.

In some examples, the cell capacity calculation unit may estimate an SOC at a start time point of the cell capacity calculation cycle and an SOC at an end time point of the cell capacity calculation cycle based on a cell voltage of each of the plurality of battery cells indicated by the voltage sensing signal or an open circuit voltage (OCV) corresponding to the cell voltage of each of the plurality of battery cells, and calculate a difference between the SOC at the start time point and the SOC at the end time point as the SOC change amount.

In some examples, the main control circuit may further include a cell capacity difference calculation unit that calculates a cell capacity difference for a cell capacity of each of the plurality of battery cells every cell capacity calculation cycle, the cell capacity difference being a change in cell capacity during the cell capacity calculation cycle for each of the plurality of battery cells.

In some examples, the cell capacity difference calculation unit may calculate, as the cell capacity difference for each battery cell, a difference between a cell capacity at a start time point of a nth cell capacity calculation cycle and a cell capacity at an end time point of the nth cell capacity calculation cycle for each of the plurality of battery cells, the “n” being a natural number greater than or equal to 1 that indicates the number of times the cell capacity calculation cycle has elapsed from a time point at which the battery pack began to be used to an arbitrary time point.

In some examples, the main control circuit may include a degradation degree diagnosis unit that stores a cell capacity difference for each of the plurality of battery cells during a cell capacity calculation cycle corresponding to a time point at which a value of the accumulated energy increases by a predetermined reference energy unit, calculates a slope between a current cell capacity difference corresponding to a current accumulation cycle and an immediately previous cell capacity difference corresponding to an immediately previous accumulation cycle for each of the plurality of battery cells, and diagnoses a battery cell for which the calculated slope is greater than or equal to a predetermined degradation threshold value as an abnormal cell.

Aspects of the disclosure provide for a method for diagnosing degrees of degradation of a plurality of battery cells constituting a battery pack by a battery management system including: computing accumulated energy for the battery pack using a battery pack current flowing through the battery pack and a battery pack voltage that is a voltage of the battery pack; calculating a cell capacity of each of the plurality of battery cells every predetermined cell capacity calculation cycle; calculating a cell capacity difference every cell capacity calculation cycle for each of the plurality of battery cells; calculating a degree of change in cell capacity difference for each of the plurality of battery cells every accumulation cycle during which the accumulated energy increases by a predetermined unit; and diagnosing whether each battery cell is abnormal according to a result of comparing the degree of change in cell capacity difference calculated every accumulation cycle with a predetermined threshold value.

In some examples, the computing of the accumulated energy may include calculating accumulated energy by multiplying a battery pack current and a battery pack voltage every monitoring cycle during a charging period in which the battery pack is charged to calculate charging energy, and integrating the charging energy calculated during the charging period, or calculating accumulated energy by multiplying a battery pack current and a battery pack voltage every monitoring cycle during a discharging period in which the battery pack is discharged to calculate discharging energy, and integrating the discharging energy calculated during the discharging period.

In some examples, the calculating of the cell capacity may include: accumulating a current flowing through each of the plurality of battery cells during the cell capacity calculation cycle and calculating an accumulated current amount of each of the plurality of battery cells; calculating an SOC change amount of each of the plurality of battery cells during the cell capacity calculation cycle; and calculating a cell capacity by dividing the accumulated current amount by the SOC change amount during the cell capacity calculation cycle for each of the plurality of battery cells.

In some examples, the cell capacity calculation cycle may be a period from a time point when the main control circuit is powered on to a time point when the main control circuit is powered off.

In some examples, the calculating of the SOC change amount may include estimating an SOC at a start time point of the cell capacity calculation cycle and an SOC at an end time point of the cell capacity calculation cycle based on a cell voltage of each of the plurality of battery cells indicated by a voltage sensing signal or an open circuit voltage (OCV) corresponding to the cell voltage of each of the plurality of battery cells, and calculating a difference between the SOC at the start time point and the SOC at the end time point as the SOC change amount.

In some examples, the calculating of the cell capacity difference may include calculating, as the cell capacity difference for each battery cell, a difference between a cell capacity at a start time point of a nth cell capacity calculation cycle and a cell capacity at an end time point of the nth cell capacity calculation cycle for each of the plurality of battery cells, the cell capacity difference being a change in cell capacity during the cell capacity calculation cycle for each of the plurality of battery cells, and the “n” being a natural number greater than or equal to 1 that indicates the number of times the cell capacity calculation cycle has elapsed from a time point at which the battery pack began to be used to an arbitrary time point.

In some examples, the calculating of the degree of change in cell capacity difference may include: storing a cell capacity difference for each of the plurality of battery cells during a cell capacity calculation cycle corresponding to a time point at which a value of the accumulated energy increases by a predetermined reference energy unit; and calculating a slope between a current cell capacity difference corresponding to a current accumulation cycle and an immediately previous cell capacity difference corresponding to an immediately previous accumulation cycle for each of the plurality of battery cells.

Aspects of the disclosure allow for at least detecting a battery cell that is abnormal due to degradation of its capacity before damage to the battery occurs.

### BRIEF DESCRIPTION OF THE DRAWINGS

FIG. 1 is a schematic diagram showing a battery system according to aspects of the disclosure.

FIG. 2 is a diagram showing a partial configuration of an MCU according to aspects of the disclosure.

FIG. 3 is a flowchart showing a method for diagnosing a degree of cell capacity degradation of a battery cell according to aspects of the disclosure.

FIG. 4 is a graph showing a relationship between a cell capacity difference and accumulated energy according to aspects of the disclosure.

### DETAILED DESCRIPTION

The suffixes “module” and/or “unit” for components used in the description below are assigned or mixed in consideration of easiness in writing the specification and do not have distinctive meanings or roles by themselves. In addition, the terms “-er”, “-or”, and “module” described in the specification refer to a unit for processing at least one function or operation, which may be implemented by hardware, software or a combination thereof.

In addition, in describing aspects of the disclosure, detailed descriptions of relevant known technologies will be omitted if they unnecessarily obscure the gist of the disclosure. Further, the accompanying drawings are provided only to help easily understand aspects of the disclosure. It should be understood that aspects of the disclosure are not limited by the accompanying drawings, and cover all modifications, equivalents, and substitutions within the spirit and the technical scope of the disclosure.

Terms including ordinal numbers such as first and second may be used to describe various components, but these components are not limited by these terms. These terms are used only for the purpose of distinguishing one component from another component.

It is to be understood that when one component is referred to as being “connected to” or “coupled to” another component, one component may be connected or coupled directly to another component or be connected or coupled to another component with an intervening component therebetween. On the other hand, it is to be understood that when one component is referred to as being “directly connected to” or “directly coupled to” another component, one component may be connected to another component with no intervening component therebetween.

It should be understood that terms “include”, “have”, and the like specify the presence of features, numerals, steps, operations, components, parts, or combinations thereof, but do not preclude the presence or addition of one or more other features, numerals, steps, operations, components, parts, or combinations thereof.

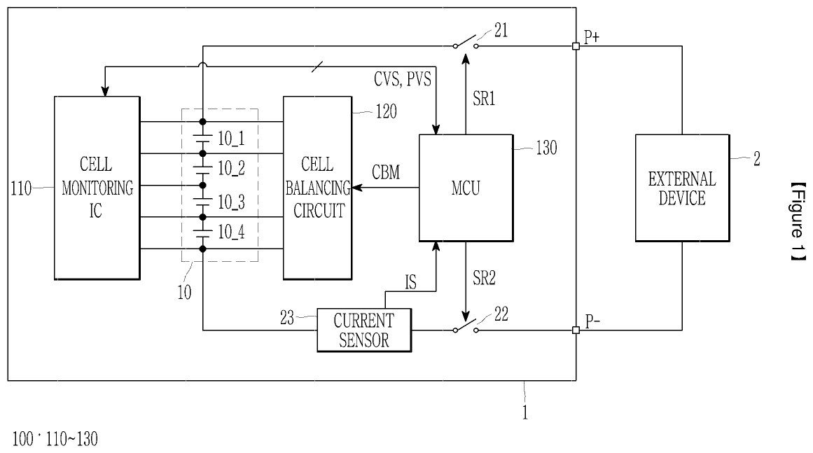

FIG. 1 is a schematic diagram showing a battery system according to an exemplary embodiment.

In FIG. 1, an external device 2 may be connected between both output terminals P+ and P− of the battery system 1, and a battery pack 10 may be electrically connected to the external device 2 when relays 21 and 22 are closed. Although it is illustrated in FIG. 1 that the external device 2 is connected to the battery system 1, this is an example to help understand the battery system 1, and the disclosure is not limited thereto.

In a case where the external device 2 is an electric load, the battery system 1 may be discharged by operating as a power supply that supplies energy to the electric load 2. The electronic load may be a moving means or an energy storage system (ESS), and the moving means may be, for example, an electric vehicle, a hybrid vehicle, or a smart mobility. In a case where the external device 2 is a charger, the battery system 1 may be charged by receiving energy from a power system through the charger 2.

The battery system 1 includes a battery pack 10, two relays 21 and 22, a current sensor 23, and a battery management system (BMS) 100.

The battery pack 10 includes a plurality of battery cells 10_1 to 10_4 connected to each other in series. Although it is illustrated in FIG. 1 that the battery pack 10 includes four battery cells 10_1 to 10_4 connected to each other in series, the disclosure is not limited thereto. For example, five or more battery cells may be connected to each other in series, or a plurality of sets, each including two or more battery cells connected in parallel, may be connected to each other in series.

The relay 21 may be connected between a positive pole of the battery pack 10 and the output terminal P+, and the relay 22 may be connected between a negative pole of the battery pack 10 and the output terminal P-, and the relays 21 and 22 may be controlled to be opened or closed according to a control of a main control unit (MCU) 130 of the BMS 100. For example, the MCU 130 may generate enable-level relay control signals SR1 and SR2 and transmit the generated enable-level relay control signals SR1 and SR2 to the relays 21 and 22, and the relays 21 and 22 may be closed according to the enable-level relay control signals SR1 and SR2. In addition, the MCU 130 may generate disable-level relay control signals SR1 and SR2 and transmit the generated disable-level relay control signals SR1 and SR2 to the relays 21 and 22, and the relays 21 and 22 may be opened according to the disable-level relay control signals SR1 and SR2. During charging or discharging of the battery pack 10, the relays 21 and 22 may be closed to constitute a charging current path or a discharging current path.

The current sensor 23 may sense a current flowing through the battery pack 10 (hereinafter referred to as a battery pack current), generate a current sensing signal IS indicating the sensed battery pack current, and transmit the generated current sensing signal IS to the MCU 130. The current flowing through the battery pack 10 may be referred to as a battery pack current. Since the plurality of battery cells 10_1 to 10_4 are connected to each other in series, a current flowing through the plurality of battery cells 10_1 to 10_4 may be the same as the battery pack current. In examples where a plurality of battery cells are connected to each other in parallel, a current sensor may be provided for each current path. In examples where the battery system 1 includes a plurality of battery packs, current sensors may be provided in the same number as the number of battery packs to measure a current flowing through each of the battery packs. The battery system 1 according to aspects of the disclosure may include current sensors in such a number as to sense a current flowing through each of the plurality of battery cells constituting the battery pack, and each of the current sensors may be connected to the corresponding battery cell in series at a location suitable for measuring a cell current of the corresponding battery cell.

The BMS 100 includes a cell monitoring integrated circuit (IC) 110, a cell balancing unit 120, and an MCU 130. The BMS 100 may be connected to the plurality of battery cells 10_1 to 10_4, control a charge/discharge current of the battery pack 10 based on information such as the cell voltage of each of the plurality of battery cells 10_1 to 10_4 and the battery pack current, and control a cell balancing operation for the plurality of battery cells 10_1 to 10_4.

For example, the cell monitoring IC 110 may measure a cell voltage of each of the plurality of battery cells 10_1 to 10_4 and a voltage of the battery pack 10 (which may be referred to as a battery pack voltage) at each monitoring cycle, and transmit voltage sensing signals CVS and PVS indicating the measured plurality of cell voltages and the measured battery pack voltage to the MCU 130. The MCU 130 may determine whether cell balancing is necessary based on the voltage sensing signal (CVS). Among the cell voltages of the plurality of battery cells 10_1 to 10_4, the lowest cell voltage may be lower than the other cell voltages by a predetermined threshold value or more, or the highest cell voltage may be higher than the other cell voltages by the predetermined threshold value or more. When a difference between the cell voltages of the plurality of battery cells 10_1 to 10_4 is greater than or equal to the predetermined threshold value, the MCU 130 may determine that cell balancing is necessary. When it is determined that cell balancing is necessary, the MCU 130 may control the cell balancing unit 120 to perform a cell balancing operation. For example, the MCU 130 may generate a control signal CBM to discharge a battery cell having a cell voltage higher than a predetermined reference voltage among the plurality of cell voltages and transmit the generated control signal CBM to the cell balancing unit 120. The cell balancing unit 120 may form a discharging path capable of discharging the battery cell having a cell voltage higher than the predetermined reference voltage, discharge the battery cell having a cell voltage higher than the predetermined reference voltage, or store energy generated while discharging the battery cell having a cell voltage higher than the predetermined reference voltage. The MCU 130 may generate a control signal CBM to charge a battery cell having a cell voltage lower than the predetermined reference voltage among the plurality of cell voltages and transmit the generated control signal CBM to the cell balancing unit 120. The cell balancing unit 120 may form a charging path capable of charging the battery cell having a cell voltage lower than the predetermined reference voltage and charge the battery cell having a cell voltage lower than the predetermined reference voltage. The energy transferred from discharged battery cell may be used for charging for cell balancing. The predetermined reference voltage may be determined based on the plurality of cell voltages. For example, an average value of the plurality of cell voltages or a median value between the plurality of cell voltages may be determined as the reference voltage.

The MCU 130 may diagnose degrees of cell capacity degradation for the plurality of battery cells 10_1 to 10_4. The MCU 130 may accumulate one of charging energy and discharging energy for the battery pack 10 and compute the accumulated energy, and calculate a degree of change (e.g., slope) in cell capacity difference for each of the plurality of battery cells 10_1 to 10_4 whenever the accumulated energy of the battery pack 10 increases by a predetermined unit. The period during which the accumulated energy increases by the reference energy unit is called an accumulation cycle. The MCU 130 may diagnose whether the battery cell is abnormal according to a result of comparing the slope calculated every accumulation cycle with a predetermined degradation threshold value. As the degree of change in cell capacity difference increases, the degree of cell capacity degradation can be considered to be greater. That is, taking into account that the degree of change in cell capacity difference increases when the cell capacity of the battery cell decreases according to the degradation of the battery cell, the degree of change in cell capacity difference be used to diagnose the degree of cell capacity degradation. According to aspects of the disclosure, the degree of change in cell capacity difference refers to a difference between a cell capacity difference at a current accumulation cycle and a cell capacity difference at a previous accumulation cycle for each battery cell. The previous accumulation cycle may be a cycle immediately preceding the current accumulation cycle. The MCU 130 may calculate a cell capacity of each of the plurality of battery cells 10_1 to 10_4 every predetermined cell capacity calculation cycle in order to calculate a cell capacity difference. The MCU 130 may calculate the cell capacity of each battery cell based on a cell voltage of each of the plurality of battery cells 10_1 to 10_4.

The MCU 130 may be implemented as a semiconductor intellectual property (IP), e.g., an application specific IC (ASIC), and a program configured by a set of control instructions for diagnosing a degree of cell capacity degradation for each of the plurality of battery cells 10_1 to 10_4 may be installed in the ASIC. Each component of the MCU 130 may be implemented by a set of control instructions for performing the same operation among all control instructions.

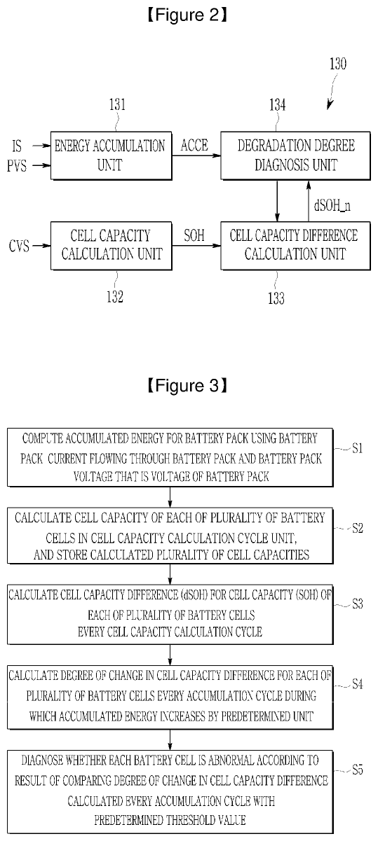

FIG. 2 is a diagram showing a partial configuration of the MCU according to aspects of the disclosure. FIG. 3 is a flowchart showing a method for diagnosing a degree of cell capacity degradation of a battery cell according to aspects of the disclosure. In FIG. 2, components for diagnosing a degree of cell capacity degradation of a battery cell are illustrated. As illustrated in FIG. 2, the MCU 130 may include an energy accumulation unit 131, a cell capacity calculation unit 132, a cell capacity difference calculation unit 133, and a degradation degree diagnosis unit 134.

The energy accumulation unit 131 may accumulate one of charging energy and discharging energy for the battery pack 10 and compute the accumulated energy. For example, the energy accumulation unit 131 may compute one of charging energy and discharging energy for the battery pack 10 as the accumulated energy, using a battery pack current indicated by the current sensing signal IS and a battery pack voltage indicated by the voltage sensing signal PVS (S1). A time at which the battery pack current indicated by the current sensing signal IS is measured and a time at which the battery pack voltage indicated by the voltage sensing signal PVS is measured may be synchronized with each other by a control of the MCU 130. For example, the MCU 130 may instruct the current sensor 23 to measure a current and the cell monitoring IC 110 to measure a battery pack voltage every predetermined monitoring cycle.

Specifically, in a case where the energy accumulation unit 131 calculates accumulated energy of charging energy, the energy accumulation unit 131 may calculate the accumulated energy by multiplying a battery pack current and a battery pack voltage every monitoring cycle during a charging period in which the battery pack 10 is charged to calculate charging energy, and integrating the charging energy calculated during the charging period. In some examples where the energy accumulation unit 131 calculates accumulated energy of discharging energy, the energy accumulation unit 131 may calculate the accumulated energy by multiplying a battery pack current and a battery pack voltage every monitoring cycle during a discharging period in which the battery pack 10 is discharged to calculate discharging energy, and integrating the discharging energy calculated during the discharging period. The energy accumulation unit 131 may transmit the calculated accumulated energy value ACCE to the degeneration degree diagnosis unit 134.

The cell capacity calculation unit 132 may calculate cell capacities for each of the plurality of battery cells 10_1 to 10_4 in units of the predetermined cell capacity calculation cycle, and store the calculated plurality of cell capacities (S2). The cell capacity indicates an amount of charge that a battery is allowed to hold, and the cell capacity may be expressed as a state of health (SOH). According to aspects of the disclosure, the SOH, which is a ratio of a current cell capacity of the battery cell to an initial cell capacity of the battery cell, may be used as a factor indicating the current cell capacity of the battery cell. The state before the battery cell is used can be called “initial”.

The cell capacity calculation cycle may be set in various ways depending on the design. For example, a period from a time point when the BMS 100 is powered on to a time point when the BMS 100 is powered off may be set as the cell capacity calculation cycle. The term “powered on” means that a power supply is connected to the BMS 100 to supply power required for operating the BMS 100, and the term “powered off” means that the power supply connected to the BMS 100 is blocked to cut off the supply of the power to the BMS 100. When the BMS 100 is powered on, the MCU 130 may also be connected to the power supply and turned on, and when the BMS 100 is powered off, the MCU 130 may also be turned off by blocking the power supply. The power-on and the power-off of the BMS 100 may be controlled according to a user's operation or according to a control instruction from a higher-level controller.

Specifically, the cell capacity calculation unit 132 may accumulate a current flowing through each of the plurality of battery cells 10_1 to 10_4 during the cell capacity calculation cycle and calculate an accumulated current amount of each of the plurality of battery cells 10_1 to 10_4, calculate an SOC change amount of each of the plurality of battery cells 10_1 to 10_4 during the cell capacity calculation cycle, and calculate a cell capacity (SOH) by dividing the accumulated current amount by the SOC change amount during the cell capacity calculation cycle for each of the plurality of battery cells 10_1 to 10_4. According to aspects of the disclosure, since the plurality of battery cells 10_1 to 10_4 may be connected to each other in series, the plurality of battery cells 10_1 to 10_4 may have the same accumulated current amount. In some examples where a plurality of battery cells are connected to each other in parallel, the battery system 1 may include a current sensor for each current path, and the cell capacity calculation unit 132 may calculate an accumulated current amount for each of the plurality of battery cells by collecting a result of measuring a current in each current path.

The cell capacity calculation unit 132 may estimate an SOC at a start time point of the cell capacity calculation cycle and an SOC at an end time point of the cell capacity calculation cycle based on a cell voltage or an open circuit voltage (OCV) of each of the plurality of battery cells 10_1 to 10_4, and calculate a difference between the SOC at the start time point and the SOC at the end time point as the SOC change amount. Concerning the method for estimating an SOC for each of the plurality of battery cells 10_1 to 10_4, any of the various known techniques may be applied. For example, the BMS 100 may include a look-up table in which condition factors are cell temperature and OCV (or cell voltage), and a factor determined according to the condition factors is SOC. The cell capacity calculation unit 132 may derive an SOC corresponding to an OCV (or a cell voltage) calculated according to a cell voltage measured at a current cell temperature from the look-up table. The cell capacity calculation unit 132 may estimate an SOC under conditions that are not recorded in the look-up table, using an interpolation method.

The cell capacity difference calculation unit 133 may calculate a cell capacity difference dSOH for a cell capacity SOH of each of the plurality of battery cells 10_1 to 10_4 every cell capacity calculation cycle (S3). The cell capacity difference according to aspects of the disclosure may refer to a change in cell capacity during the cell capacity calculation cycle for each of the plurality of battery cells 10_1 to 10_4. Therefore, the cell capacity difference calculation unit 133 may calculate, as a cell capacity difference dSOH_n for each of the plurality of battery cells 10_1 to 10_4, a difference SOH_n1-SOH_n2 between a cell capacity SOH_n1 at a start time point of a nth cell capacity calculation cycle and a cell capacity SOH_n2 at an end time point of the nth cell capacity calculation cycle. “n” may be a natural number greater than or equal to 1 that indicates the number of times the cell capacity calculation cycle has elapsed from a time point at which the battery pack 10 began to be used to an arbitrary time point (e.g., a current time).

The degradation degree diagnosis unit 134 may calculate a degree of change in cell capacity difference for each of the plurality of battery cells 10_1 to 10_4 every accumulation cycle during which accumulated energy increases by a predetermined unit (S4).

The degradation degree diagnosis unit 134 receives an accumulated energy value from the energy accumulation unit 131, receives from the cell capacity difference calculation unit 133 and stores a cell capacity difference dSOH for each of the plurality of battery cells 10_1 to 10_4 during a cell capacity calculation cycle corresponding to a time point at which the accumulated energy value increases by a predetermined reference energy unit, and calculates a degree of change (e.g., slope) between a cell capacity difference corresponding to a current accumulation cycle (hereinafter, a current cell capacity difference dSOH_n) and a cell capacity difference corresponding to an immediately previous accumulation cycle (hereinafter, an immediately previous cell capacity difference dSOH_n−1) for each of the plurality of battery cells 10_1 to 10_4 (S4). The accumulation cycle is updated every time the accumulated energy value increases by the reference energy unit.

When the accumulation cycle is updated (when the accumulated energy value increases by the reference energy unit), the degradation degree diagnosis unit 134 may request the cell capacity difference calculation unit 133 for a cell capacity difference for each of the plurality of battery cells 10_1 to 10_4. The cell capacity calculation unit 132 may transmit a current cell capacity difference dSOH_n, which is a cell capacity difference calculated at a time point closest to the time point at which the request is received, to the degradation degree diagnosis unit 134. The degradation degree diagnosis unit 134 may store the current cell capacity difference dSOH_n received in response to the request. The degradation degree diagnosis unit 134 calculates a slope between the current cell capacity difference dSOH_n and the immediately previous pre-stored cell capacity difference dSOH_n−1 every accumulation cycle. For example, the degradation degree diagnosis unit 134 may calculate the slope by dividing a value obtained by subtracting the immediately previous cell capacity difference dSOH_n−1 from the current cell capacity difference dSOH_n by the reference energy. Since the cell capacity is a ratio of a cell capacity at a time point when the cell capacity is calculated to the initial cell capacity of the battery cell, the unit of the cell capacity may be [%]. The unit of the accumulated energy may be [J] (joule).

The degradation degree diagnosis unit 134 may diagnose whether each battery cell is abnormal according to a result of comparing the degree of change in cell capacity difference calculated every accumulation cycle with a predetermined threshold value (S5). The degradation degree diagnosis unit 134 may diagnose a battery cell for which the calculated slope is greater than or equal to the predetermined degradation threshold value among the plurality of battery cells 10_1 to 10_4 as an abnormal cell.

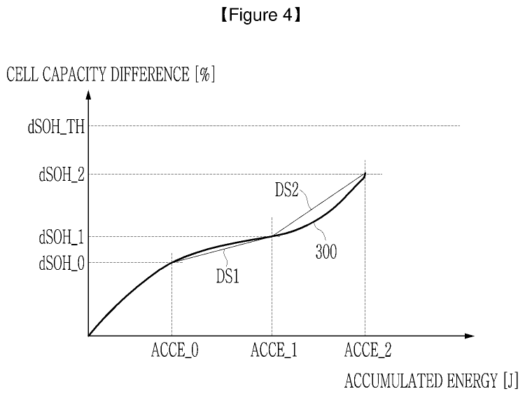

FIG. 4 is a graph showing a relationship between a cell capacity difference and accumulated energy according to aspects of the disclosure. FIG. 4 is an example and the disclosure is not limited thereto.

In FIG. 4, the horizontal axis is an axis related to accumulated energy, on which a position indicating accumulated energy moves further in the rightward direction as the accumulated energy increases, and the vertical axis is an axis related to a cell capacity difference, on which a position indicating a cell capacity difference moves further in the upward direction as the cell capacity difference increases.

“dSOH_TH” shown on the vertical axis of FIG. 4 is a fixed value, and is a cell capacity difference threshold value for determining whether a battery cell is normal. Conventionally, when the cell capacity difference reaches “dSOH_TH”, the corresponding cell can be diagnosed as a cell that is abnormal due to degradation.

A graph 300 illustrated in FIG. 4 is a graph showing a cell capacity difference with respect to accumulated energy of a certain battery cell among the plurality of battery cells 10_1 to 10_4.

At a time point when the accumulated energy reaches “ACCE_1”, the degradation degree diagnosis unit 134 calculates a slope DS1 between an immediately previous cell capacity difference dSOH_0 when the accumulated energy is “ACCE_0” and a current cell capacity difference dSOH_1 when the accumulated energy is “ACCE_1”. The slope DS1 has a value smaller than the degradation threshold value, and the degradation degree diagnosis unit 134 determines that the battery cell is normal.

At a time point when the accumulated energy reaches “ACCE_2”, the degradation degree diagnosis unit 134 calculates a slope DS2 between an immediately previous cell capacity difference dSOH_1 when the accumulated energy is “ACCE_1” and a current cell capacity difference dSOH_2 when the accumulated energy is “ACCE_2”. The slope DS2 has a value greater than or equal to the degradation threshold value, and the degradation degree diagnosis unit 134 determines that the battery cell is abnormal.

The degradation threshold value may be a constant value or a value that varies depending on accumulated energy. For example, as the accumulated energy increases, the degradation threshold value may increase.

According to aspects of the disclosure, as compared to the conventional method, even though the current cell capacity difference dSOH_2 is smaller than “dSOH_TH”, it can be determined that the corresponding battery cell is abnormal. According to the conventional method, while the cell capacity difference of the battery cell progresses from the current cell capacity difference dSOH_2 to “dSOH_TH”, the other battery cells may be affected. In contrast, the battery system according to aspects of the disclosure are capable of detecting an abnormal battery cell of which a degree of cell capacity degradation is high at an early stage by calculating a degree of change in cell capacity difference.

When an abnormal battery cell is detected, the BMS 100 may notify the outside. The outside may include a terminal or server that manages the battery system 1, a higher-level controller of a device on which the battery system 1 is mounted, or the like. By detecting an abnormal battery cell, if the abnormal battery cell is replaced in the battery pack 10, the influences on degrees of cell capacity degradation of the other battery cells can be blocked.

Although aspects of the disclosure have been described in detail above, the scope of the disclosure is not limited thereto. Various modifications and improvements made by those skilled in the art using aspects of the disclosure defined in the appended claims also fall within the scope of the disclosure.

1-15. (canceled)

16. A battery system comprising:
a battery pack including a plurality of battery cells;
a current sensor configured to:
measure a current flowing through the battery pack; and
generate a current sensing signal indicating the measured battery pack current;
a cell monitoring integrated circuit (IC) configured to:
measure a battery pack voltage of the battery pack and a cell voltage of each of the plurality of battery cells; and
generate a voltage sensing signal indicating the measured battery pack voltage and the measured plurality of cell voltages; and
a main control circuit configured to:
compute accumulated energy for the battery pack using the current sensing signal and the voltage sensing signal;
calculate a cell capacity of each of the plurality of battery cells at predetermined cell capacity calculation cycles;
calculate a degree of change in cell capacity difference for each of the plurality of battery cells at accumulation cycles during which the accumulated energy increases by a predetermined unit; and
diagnose whether each battery cell is abnormal or normal based on comparing a degree of change in cell capacity difference calculated at the accumulation cycles with a predetermined threshold value.

17. The battery system of claim 16, wherein the main control circuit includes an energy accumulation unit configured to compute at least one of charging energy or discharging energy for the battery pack as the accumulated energy using a battery pack current indicated by the current sensing signal and a battery pack voltage indicated by the voltage sensing signal.

18. The battery system of claim 17, wherein the energy accumulation unit is configured to:
calculate accumulated energy by multiplying a battery pack current and a battery pack voltage at monitoring cycles during a charging period in which the battery pack is charged to calculate charging energy and integrating the charging energy calculated during the charging period; or
calculate accumulated energy by multiplying a battery pack current and a battery pack voltage at monitoring cycles during a discharging period in which the battery pack is discharged to calculate discharging energy and integrating the discharging energy calculated during the discharging period.

19. The battery system of claim 16, wherein the main control circuit includes a cell capacity calculation unit configured to:
calculate cell capacities for each of the plurality of battery cells in units of the cell capacity calculation cycle, the cell capacity calculation cycle being a period from a time point when the main control circuit is powered on to a time point when the main control circuit is powered off; and
store the calculated cell capacities.

20. The battery system of claim 19, wherein the cell capacity calculation unit is configured to:
accumulate a current flowing through each of the plurality of battery cells during the cell capacity calculation cycle and calculate an accumulated current amount of each of the plurality of battery cells;
calculate a state of charge (SOC) change amount of each of the plurality of battery cells during the cell capacity calculation cycle; and
calculate a cell capacity by dividing the accumulated current amount by the SOC change amount during the cell capacity calculation cycle for each of the plurality of battery cells.

21. The battery system of claim 20, wherein the cell capacity calculation unit is configured to:
estimate an SOC at a start time point of the cell capacity calculation cycle and an SOC at an end time point of the cell capacity calculation cycle based on a cell voltage of each of the plurality of battery cells indicated by the voltage sensing signal or an open circuit voltage (OCV) corresponding to the cell voltage of each of the plurality of battery cells; and
calculate a difference between the SOC at the start time point and the SOC at the end time point as the SOC change amount.

22. The battery system of claim 19, wherein the main control circuit includes a cell capacity difference calculation unit configured to calculate a cell capacity difference for a cell capacity of each of the plurality of battery cells at cell capacity calculation cycles, the cell capacity difference being a change in cell capacity during the cell capacity calculation cycle for each of the plurality of battery cells.

23. The battery system of claim 22, wherein the cell capacity difference calculation unit is configured to calculate, as the cell capacity difference for each battery cell, a difference between a cell capacity at a start time point of a nth cell capacity calculation cycle and a cell capacity at an end time point of the nth cell capacity calculation cycle for each of the plurality of battery cells, the “n” being a natural number greater than or equal to 1 that indicates the number of times the cell capacity calculation cycle has elapsed from a time point at which the battery pack began to be used to an arbitrary time point.

24. The battery system of claim 16, wherein the main control circuit includes a degradation degree diagnosis unit configured to:
store a cell capacity difference for each of the plurality of battery cells during a cell capacity calculation cycle corresponding to a time point at which a value of the accumulated energy increases by a predetermined reference energy unit;
calculate a slope between a current cell capacity difference corresponding to a current accumulation cycle and an immediately previous cell capacity difference corresponding to an immediately previous accumulation cycle for each of the plurality of battery cells; and
diagnose a battery cell for which the calculated slope is greater than or equal to a predetermined degradation threshold value as an abnormal cell.

25. A method for diagnosing degrees of degradation of a plurality of battery cells constituting a battery pack by a battery management system, the method comprising:
computing accumulated energy for the battery pack using a battery pack current flowing through the battery pack and a battery pack voltage that is a voltage of the battery pack;
calculating a cell capacity of each of the plurality of battery cells at predetermined cell capacity calculation cycles;
calculating a degree of change in cell capacity difference for each of the plurality of battery cells at accumulation cycles during which the accumulated energy increases by a predetermined unit; and
diagnosing whether each battery cell is abnormal or normal based on comparing the degree of change in cell capacity difference calculated at the accumulation cycles with a predetermined threshold value.

26. The method of claim 25, further comprising computing at least one of charging energy or discharging energy for the battery pack as the accumulated energy using the battery pack current and the battery pack voltage.

27. The method of claim 26, wherein computing the accumulated energy includes:
calculating accumulated energy by multiplying a battery pack current and a battery pack voltage at monitoring cycles during a charging period in which the battery pack is charged to calculate charging energy and integrating the charging energy calculated during the charging period; or
calculating accumulated energy by multiplying a battery pack current and a battery pack voltage at monitoring cycles during a discharging period in which the battery pack is discharged to calculate discharging energy and integrating the discharging energy calculated during the discharging period.

28. The method of claim 25, further comprising calculating cell capacities for each of the plurality of battery cells in units of the cell capacity calculation cycle, the cell capacity calculation cycle being a period from a time point when a control circuit is powered on to a time point when the control circuit is powered off.

29. The method of claim 28, wherein calculating the cell capacity includes:
accumulating a current flowing through each of the plurality of battery cells during the cell capacity calculation cycle and calculating an accumulated current amount of each of the plurality of battery cells;
calculating a state of charge (SOC) change amount of each of the plurality of battery cells during the cell capacity calculation cycle; and
calculating a cell capacity by dividing the accumulated current amount by the SOC change amount during the cell capacity calculation cycle for each of the plurality of battery cells.

30. The method of claim 29, wherein the calculating of the SOC change amount includes:
estimating an SOC at a start time point of the cell capacity calculation cycle and an SOC at an end time point of the cell capacity calculation cycle based on a cell voltage of each of the plurality of battery cells indicated by a voltage sensing signal or an open circuit voltage (OCV) corresponding to the cell voltage of each of the plurality of battery cells; and
calculating a difference between the SOC at the start time point and the SOC at the end time point as the SOC change amount.

31. The method of claim 28, further comprising calculating a cell capacity difference for a cell capacity of each of the plurality of battery cells at cell capacity calculation cycles, the cell capacity difference being a change in cell capacity during the cell capacity calculation cycle for each of the plurality of battery cells.

32. The method of claim 31, wherein calculating the cell capacity difference includes calculating, as the cell capacity difference for each battery cell, a difference between a cell capacity at a start time point of a nth cell capacity calculation cycle and a cell capacity at an end time point of the nth cell capacity calculation cycle for each of the plurality of battery cells, the “n” being a natural number greater than or equal to 1 that indicates the number of times the cell capacity calculation cycle has elapsed from a time point at which the battery pack began to be used to an arbitrary time point.

33. The method of claim 25, wherein:
calculating the degree of change in cell capacity difference includes:
storing a cell capacity difference for each of the plurality of battery cells during a cell capacity calculation cycle corresponding to a time point at which a value of the accumulated energy increases by a predetermined reference energy unit; and
calculating a slope between a current cell capacity difference corresponding to a current accumulation cycle and an immediately previous cell capacity difference corresponding to an immediately previous accumulation cycle for each of the plurality of battery cells; and
diagnosing whether each battery cell is abnormal or normal includes diagnosing a battery cell for which the calculated slope is greater than or equal to a predetermined degradation threshold value as an abnormal cell.

34. A battery management system comprising one or more processors configured to:
compute accumulated energy for the battery pack using a battery pack current flowing through the battery pack and a battery pack voltage that is a voltage of the battery pack;
calculate a cell capacity of each of the plurality of battery cells at predetermined cell capacity calculation cycles;
calculate a degree of change in cell capacity difference for each of the plurality of battery cells at accumulation cycles during which the accumulated energy increases by a predetermined unit; and
diagnose whether each battery cell is abnormal or normal based on comparing the degree of change in cell capacity difference calculated at the accumulation cycles with a predetermined threshold value.

35. The battery management system of claim 34, wherein the processors are further configured to:
store a cell capacity difference for each of the plurality of battery cells during a cell capacity calculation cycle corresponding to a time point at which a value of the accumulated energy increases by a predetermined reference energy unit;
calculate a slope between a current cell capacity difference corresponding to a current accumulation cycle and an immediately previous cell capacity difference corresponding to an immediately previous accumulation cycle for each of the plurality of battery cells; and
diagnose a battery cell for which the calculated slope is greater than or equal to a predetermined degradation threshold value as an abnormal cell.
